(19) United States
(12) Patent Application Publication
(10) Pub. No.: US 2014/0231914 A1
(43) Pub. Date: Aug. 21, 2014

(54) FIN FIELD EFFECT TRANSISTOR FABRICATED WITH HOLLOW REPLACEMENT CHANNEL

(71) Applicant: Applied Materials, Inc., (US)

(72) Inventors: Chorng-Ping Chang, Saratoga, CA (US); Bingxi Wood, Cupertino, CA (US)

(73) Assignee: Applied Materials, Inc., Santa Clara, CA (US)

(21) Appl. No.: 13/770,993

(22) Filed: Feb. 19, 2013

(51) Int. Cl. H01L 27/12; H01L 29/66

(52) U.S. Cl. CPC H01L 27/1211; H01L 29/66742
USPC 257/347; 438/151

(57) ABSTRACT

A method for forming a FinFET comprises forming a raised fin between isolation trenches on a substrate. A plurality of sacrificial features is formed on at least a portion of the raised fin, the sacrificial features including a sacrificial gate dielectric and a sacrificial gate electrode having sidewalls. The sacrificial features on the raised fin are removed to form a hollow channel. Channel material is selectively and epitaxially grown in the hollow channel to form a channel.

### BACKGROUND

Embodiments of the present invention relate to transistors fabricated using semiconductor processing methods.

Transistors are fundamental building blocks of integrated circuits, and as such, are being scaled to smaller and smaller sizes to allow production of ever smaller or more complex integrated circuits. A transistor is a semiconducting device capable of amplifying or switching electronic signals and electrical power. A metal-oxide-semiconductor FET (MOSFET) uses metal gate, oxide insulation, and semiconducting layers that conduct with electrons in an n-channel FET or holes in a p-channel FET. Conventional FETs have four terminals named the source, gate, drain, and active region or body. Conventional FETs are formed mostly in a single plane with the source and drain connected by a channel built into a silicon substrate and topped off by a gate over a thin gate insulating layer. Voltage on the gate causes a conductive path to form in the channel allowing current to flow between the source and the drain. However, when such structures are made ever smaller, the source and drain are separated by a short distance of mere nanometers, causing electrons to leak through the lower part of the channel even when the voltage on the gate is removed. This electron leakage wastes electrical power, causes heat buildup requiring constant cooling of computers, and results in faster draining of battery power.

A FinFET (fin field effect transistor) is a three-dimensional, non-planar, multi-gate transistor which is generally more power efficient and exhibits less electron leakage than conventional FETs. In a FinFET, the channel connecting the source and drain is a thin, finlike wall jutting out of the silicon substrate. The gate is draped over the channel on three sides like a lowercase “n” so that the current is constrained only to the raised channel, and electrons no longer have a leakage path. FinFETs are also called multigate transistors because the wrapped gate is like having three gates instead of one.

FinFET structures typically require many and/or complex fabrication steps to fabricate the jutting-out fin and channel and their ancillary gate. Further, it is difficult to fabricate a channel composed of compounds other than pure silicon because such fabrication processes often require deposition of a thick layer of the non-silicon channel material, and the thicker layer has more defects resulting from lattice mismatch, exhibits thermal expansion mismatch stresses, and requires use of non-traditional or more complex deposition processes. For example, to fabricate a FIN-FET comprising a channel of germanium by conventional processing methods, a thick layer of germanium having a thickness of at least about 1000 angstroms, or even 1 micron, or even higher, has to be deposited on a silicon wafer, and this thicker layer has more defects due to the inherent lattice mismatch between silicon and germanium. The thick germanium layer is also vulnerable to higher activation temperatures to activate dopant ions which can cause diffusion of germanium into the silicon wafer. Still further, the process and apparatus for depositing thick germanium layers are not commonly used in the semiconductor industry, resulting in higher processing and equipment costs. It is also difficult to fabricate the germanium channel in the right position between the source and drain.

For reasons that include these and other deficiencies, and despite the development of various FINFET structures and fabrication methods, further improvements in FINFET structures and fabrication methods are continuously being sought.

### SUMMARY

A method for forming a FinFET comprises forming a raised fin between isolation trenches on a substrate. A plurality of sacrificial features is formed on at least a portion of the raised fin, the sacrificial features including a sacrificial gate dielectric and a sacrificial gate electrode having sidewalls. The sacrificial features on the raised fin are removed to form a hollow channel. Channel material is selectively and epitaxially grown in the hollow channel to form a channel.

In another version, the method comprises forming a raised fin composed of silicon between shallow isolation trenches on a substrate. A plurality of sacrificial features is formed on at least a portion of the raised fin, the sacrificial features including an underling sacrificial gate dielectric, an overlying sacrificial gate electrode having sidewalls, and a sacrificial dielectric cap formed over the sacrificial gate electrode. Sidewall spacers are formed on the sidewalls of the sacrificial gate electrode. A source and drain are formed on another portion of the raised fin. The sacrificial features on the raised fin are removed to form a hollow channel. Channel material is selectively and epitaxially grown in the hollow channel to form a channel.

A FinFet structure comprises a substrate comprising a semiconductor raised fin comprising a first semiconducting material. A source and a drain are on a portion of the semiconductor raised fin, and an epitaxially grown channel is on another portion of the semiconductor raised fin. The channel is composed of a second semiconducting material that is a different material from the first semiconducting material. A gate electrode is disposed above the channel and between the source and drain.

### DRAWINGS

These features, aspects and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIGS. 1A and 1B are flowcharts of an exemplary embodiment of a process for fabricating a FINFET on a substrate;

FIG. 2A is a schematic side cross-sectional view of a semiconductor substrate with a raised fin and surrounding isolation trenches, and a sacrificial gate dielectric on the raised fin;

FIG. 2A′ is a schematic front cross-sectional view of the substrate of FIG. 2A along line A′-A′;

FIG. 2A1 is a schematic side cross-sectional view of an SOI substrate with a raised fin and surrounding isolation trenches;

FIG. 2B is a schematic side cross-sectional view of the substrate of FIG. 2A after forming a sacrificial gate electrode, sacrificial dielectric cap and sidewall spacers;

FIG. 2B′ is a schematic front cross-sectional view of the substrate of FIG. 2B along line B′-B′;

FIG. 2B1 is a schematic perspective view of the substrate of FIG. 2B;

FIG. 2C is a schematic side cross-sectional view of the substrate of FIG. 2B after etching of the sacrificial gate dielectric and epitaxial deposition of the source and drain;

FIG. 2D is a schematic cross-sectional view of the substrate of FIG. 2C after deposition of the pre-metal dielectric (PMD) over the source and drain, chemical-mechanical planarization of the PMD, and etching away of the sacrificial gate electrode to form a hollow trench;

FIG. 2E is a schematic cross-sectional view of the substrate of FIG. 2D after etching away of the sacrificial gate dielectric to form a hollow channel adjoining the hollow trench;

FIG. 2F is a schematic cross-sectional view of the substrate of FIG. 2E after selective epitaxial growth of channel material in the hollow channel to form the channel;

FIG. 2G is a schematic cross-sectional view of the substrate of FIG. 2E after deposition of the gate dielectric layer and gate electrode on the channel; and

FIG. 2G1 is a schematic perspective view of the substrate of FIG. 2G.

### DESCRIPTION

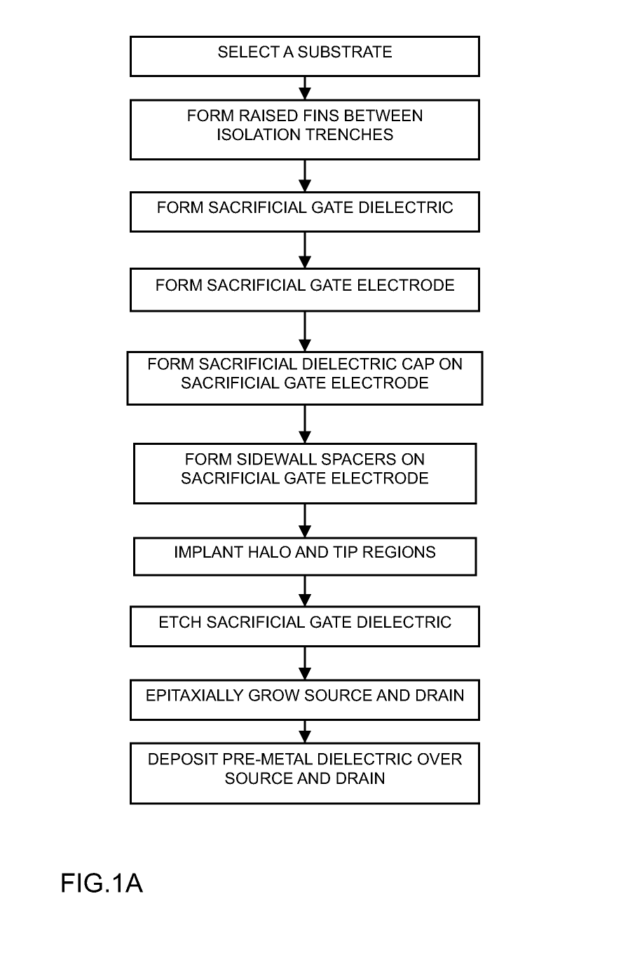

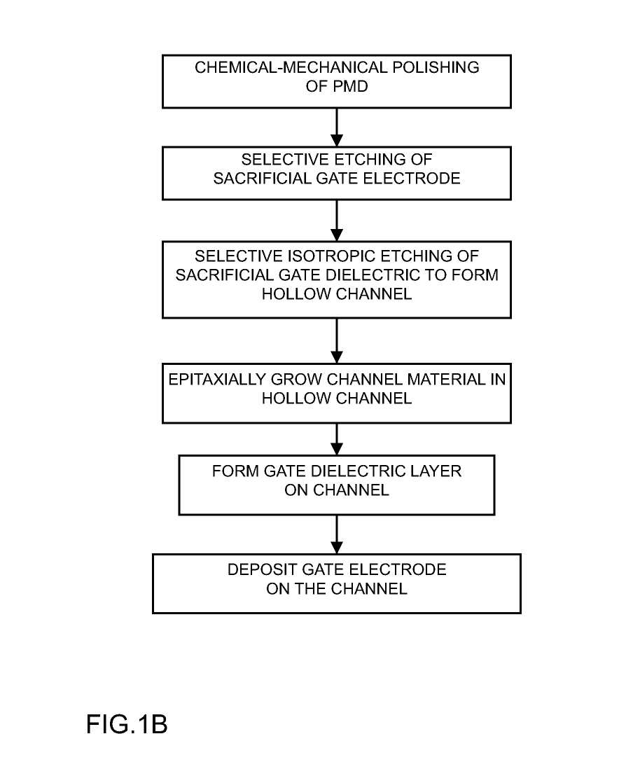

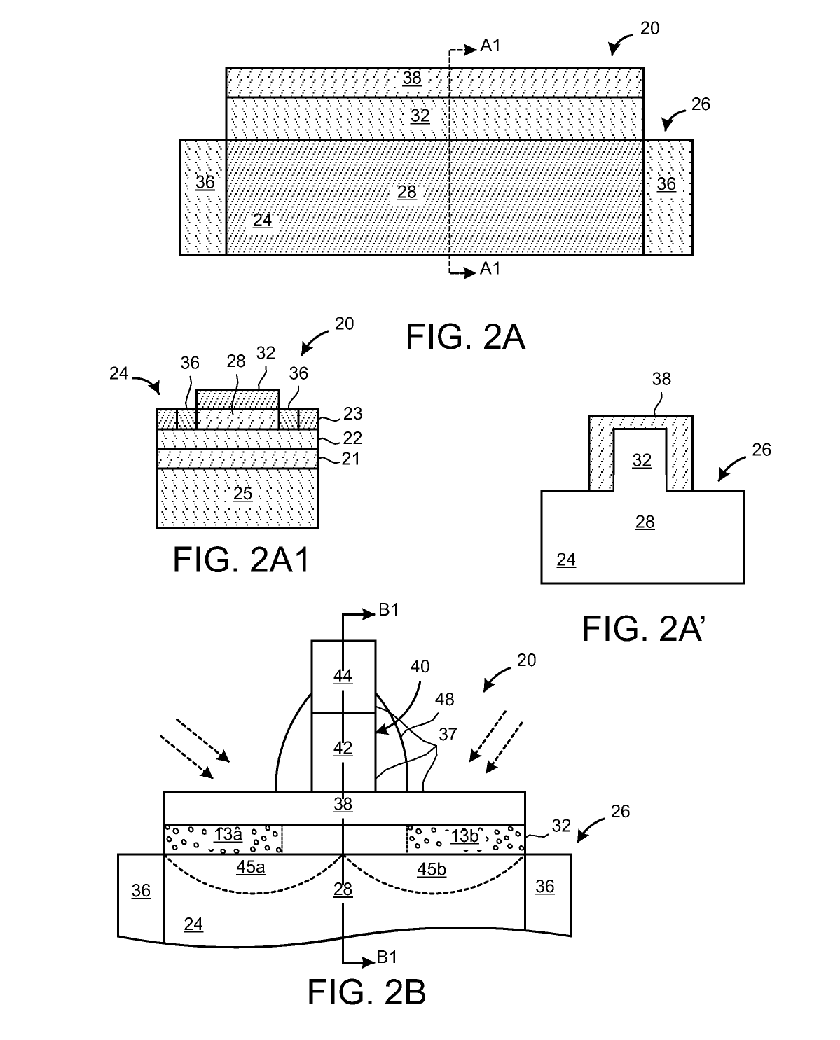

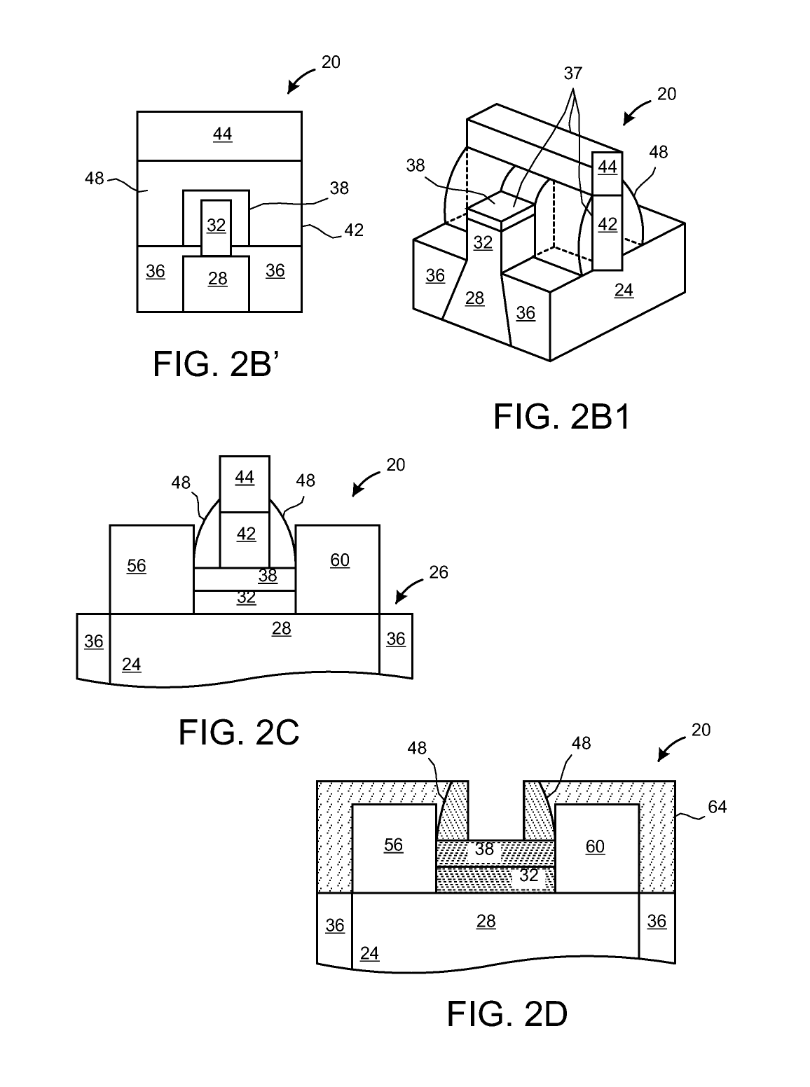

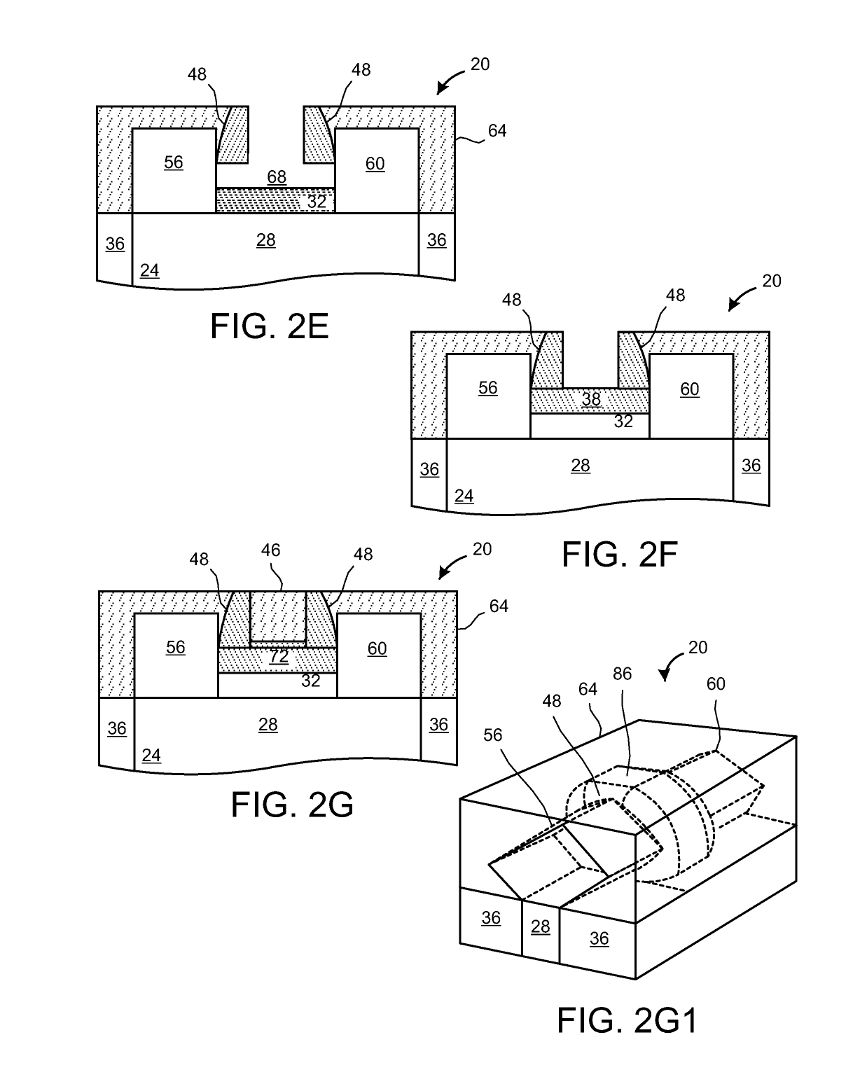

An exemplary embodiment of a process for fabricating a FinFET (fin field effect transistor) 20 formed on a substrate 24 is illustrated in FIGS. 1 and 2A to 2G1. Referring to FIG. 1, in a first step a substrate 24 is selected from, for example, a semiconductor wafer, SOI (silicon-on-insulator) substrate, or a display substrate, as shown in FIG. 2A. The substrate 24 comprises a semiconductor material, such as a silicon wafer (Si), germanium (Ge), or compound semiconductor from Groups III-V and II-VI. Exemplary compound semiconductors comprise for example, gallium arsenide (GaAs), indium phosphate (InP), zinc selenide (ZnSe), indium gallium arsenide (InGaAs), aluminum gallium arsenide (AlGaAs) or indium aluminum arsenide (InAlAs).

In one version, the substrate 24 is a silicon-on-insulator (SOI) substrate as shown in FIG. 2A1. For example, the SOI substrate 24 can include (i) a bottom semiconductor layer 21, a middle insulating layer 22 comprising an oxide or nitride such as silicon dioxide or silicon nitride, and a top semiconductor layer 23 (commonly referred to as the SOI layer) upon which active devices such as the FinFet 20 are built. In an SOI substrate 24, the underlying support 25 of the substrate 24 can be made from the semiconductor material or wafer, or a dielectric material such as borophosphosilicate glass, phosphosilicate glass, borosilicate glass and phosphosilicate glass. The SOI substrate 24 can be formed using conventional processes such as for example SIMOX (separation by ion implantation of oxygen) or bonding with an optional thinning step following the bonding process to reduce the thickness of the top semiconductor layer 23 to about 100 to about 1000 angstrom.

The top semiconductor portion of a substrate 24 as shown in FIGS. 2A to 2G1, which can be the top portion of the substrate 24 itself or a top semiconductor layer 23 deposited on a support 25, is processed to form one or more raised fins 32 each of which extend outwardly from active regions 28 of semiconductor material. The raised fins 32 rise above the top surface 26 of the substrate 24 and are made of semiconducting material. The active regions 28 and raised fins 32 are surrounded on some or all of their sides with isolation trenches 36, as shown in FIGS. 2A and 2A1. The raised fins 32 are formed by conventional photolithographic processes in which patterned resist features is formed on the substrate 24 to cover portions of the substrate 24 that subsequently define the raised fins 32. The patterned resist features can comprise photoresist and/or hard mask layers. Thereafter, conventional etching processes such as reactive ion etching (RIE) processes are used to etch the exposed regions of the substrate 24 between the patterned resist features to form the raised fins 32 and the isolation trenches 36 on either or all the sides of the raised fins 32. The raised fins 32 can also be formed by depositing a layer of a semiconductor material, which can be the same material as the substrate, or a different semiconductor material, and thereafter, using conventional lithography methods to etch trenches into the layer of the semiconductor material to define the raised fins 32 therebetween. In an exemplary embodiment, the raised fins 32 extend out of the substrate 24 to have a step height from the top surface of the isolation trenches 36 of from about 5 to about 50 nm, or even from about 3 to about 100 nm, and have a width of from about 5 to about 30 nm.

In the exemplary embodiment shown in FIGS. 2A, 2A′, and 2B to 2G′, both the substrate 24 and the raised fins 32 are composed of silicon as the substrate 24 is a silicon wafer. The isolation trenches 36 are trenches filled with dielectric material that electrically isolate and separate the active regions 28 and raised fins 32 of each FinFET 20 from other FinFETs or other devices formed in or on the substrate 24. The isolation trenches 36 can be formed for example by using conventional shallow trench isolation (STI) techniques. In one version of, the isolation trenches 36 can be shallow isolation trenches which are formed by conventional photolithographic processes in which a patterned resist features is formed on the substrate 24 to cover the active regions 28 and raised fins 32. The patterned resist features can comprise photoresist and/or hard mask layers. Thereafter, conventional reactive ion etching (RIE) processes are used to etch the exposed regions of the substrate between the patterned resist features to form shallow trenches. Thereafter, the patterned resist features are removed by conventional resist removal methods, and the shallow trenches are then filled with a dielectric material to form the isolation trenches 36. The dielectric material can be a composite of thermally grown silicon dioxide, deposited silicon nitride, deposited silicon oxide, or other such materials. The dielectric material in the shallow trenches can be deposited using a conventional chemical vapor deposition (CVD) process, such as a low pressure CVD (LPCVD) or plasma enhanced CVD (PECVD). While this exemplary embodiment is being described to illustrate a FinFET 20 fabricated according to the present invention, the exemplary embodiment should not be used to limit the scope of the invention.

In the next step, a plurality of sacrificial features 37 are formed on at least a portion of the raised fin 32 as shown in FIGS. 2A to 2C. The sacrificial features 37 include a sacrificial gate dielectric 38 which is formed to surround the exposed portions of the raised fins 32 as shown in FIG. 2A′. The sacrificial gate dielectric 38 can be formed by a thermal oxidation process or CVD deposition of a dielectric material such as the aforementioned dielectric materials. The sacrificial gate dielectric 38 can be thin with a thickness of from about 20 to about 50 angstrom, or even from about 10 to about 70 angstroms. When the raised fins 32 of formed of silicon, advantageously, a thermal oxidation process can be used to form the sacrificial gate dielectric 38. The thermal oxidation process reduces the width of the raised fins 32, which is desirable to form a smaller foot print for the FinFET 20. As an example, a raised fin 32 of silicon having a width of 15 nm when subjected to a thermal oxidation process forms a silicon dioxide layer having a thickness of about 5 nm which extends into the 15 nm width fin on either side, effectively reducing the thickness of the raised fin 32 to about 5 nm. A suitable thermal oxidation processing system is the RADIANCE CENTURA system manufactured by Applied Materials (Santa Clara, Calif.).

Thereafter, another sacrificial feature 37 comprising a sacrificial gate electrode 42 is formed on or overlying the sacrificial gate dielectric 38, as shown in FIGS. 2B and 2B′. The sacrificial gate electrode 42 comprises sidewalls 40 that extend vertically upward from top surface of the underlying sacrificial gate dielectric 38. The sacrificial gate electrode 42 may be composed of any material suitable for patterning and for ultimate selective removal. In one embodiment, the sacrificial gate electrode 42 is composed of a semiconductor material such as, but not limited to, poly-crystalline silicon, doped poly-crystalline silicon, amorphous silicon, doped amorphous silicon or a silicon-germanium alloy. In another embodiment, the sacrificial gate electrode 42 is composed of an insulating material such as, but not limited to, silicon dioxide, silicon oxy-nitride or silicon nitride. The sacrificial gate electrode 42 can be composed of, for example, polysilicon deposited by conventional polysilicon deposition processes such as LPCVD. The deposited polysilicon or other material of the sacrificial gate electrode 42 can be chemical-mechanical polished to provide a flat top surface. The polished gate electrode 42 is then selectively etched using conventional lithographic and etching processes to define the shape of each sacrificial gate electrode 42 without excessively etching the underlying sacrificial gate dielectric 38. For example, a sacrificial gate electrode 42 composed of polysilicon can be etched using a reactive ion etching process in which a capacitively coupled plasma is formed from an etching gas chemistry comprising Cl₂ and HBr.

Before etching of the sacrificial gate electrode 42, optionally, another sacrificial feature 37 comprising a sacrificial dielectric cap 44 is formed over and on the top surface of the sacrificial gate electrode 42. The sacrificial dielectric cap 44 protects the underlying gate electrode 42 during the etching of the sidewall spacers 48. The dielectric cap 44 can be a layer of silicon nitride or silicon dioxide (or other material that can have an etching selectivity ratio to etching of the sidewall spacers which is higher than 1 and is compatible to subsequent thermal processes) deposited on top of the sacrificial gate electrode 42, which is selectively etched to form the desired shape of the dielectric cap 44 prior to or at the same time as etching of the gate electrodes 42. The dielectric cap 44 can be a silicon nitride layer deposited by a thermal or PECVD process as described below.

Sidewall spacers 48 are formed on the sidewalls 40 of the sacrificial gate electrode 42 also as shown in FIGS. 2B, 2B′ and 2B1. The sidewall spacers 48 can be formed of a dielectric material which is shaped using conventional lithographic and chemical vapor deposition methods. For example, the sidewall spacers 48 can be formed by depositing a conformal layer of a silicon oxide or silicon nitride material, and then using anisotropic etching methods, such as RIE to remove the oxide or nitride material from all the horizontal surfaces, while keeping the material deposited on the vertical sidewall surfaces 40 adjacent to the sacrificial gate electrode 42. An exemplary plasma enhanced chemical vapor deposition (PECVD) process for depositing silicon nitride can use a process gas comprising (i) a silicon-containing component can be, for example, silane, disilane, trimethylsilyl (TMS), tris(dimethylamino)silane (TDMAS), bis(tertiary-butylamino)silane (BTBAS), dichlorosilane (DCS), and combinations thereof; and (ii) a nitrogen-containing component can be, for example, ammonia, nitrogen, and combinations thereof.

Thereafter, optional halo and tip ion implantation processes can be conducted to implant the ions into the raised fins 32 to form the tip regions 43a,b and the halo regions 45a,b, as shown in FIG. 2B. In this step, the sacrificial gate electrode 42 and sidewall spacers 48 serve as an ion implant mask which prevents doping of the portion of the raised fin 32 lying directly under these structures. In the halo implantation process, dopant ions which are the opposite to that placed in the subsequently formed source 56 and drain 60 are implanted into the active region 28 to form buried doped, halo regions 45a,b under the channel region and junction walls of the subsequently formed source 56 and drain 60 which the limit the extent of depletion regions. For example, for an N-channel implanted with n-type dopant, the halo regions 45a,b are implanted with a p-type dopant, and vice versa. In the tip implantation process, a dosage of dopant ions which are the same type as the dopant used in the subsequently formed source 56 and drain 60 are implanted into the fin 32 to form a thin, heavily doped source-drain extension adjacent to the channel region of the fin 32. Suitable n-type dopant ions in silicon include, for example, at least one of phosphorous, arsenic and antimony. Suitable p-type dopant ions in silicon include, for example, at least one of boron, and indium. In one version, the channel 72 comprises an n-type dopant such as arsenic, which is also implanted into the tip regions 43a,b whereas a p-type dopant such as boron is implanted into the halo regions 45a,b. In one example, the halo regions 45a,b are implanted to have a dosage level of from about 1×10¹³ atoms/cm² to about 1×10¹⁴ atoms/cm², and the tip regions 43a,b are implanted to have a dosage level of from about 1×10¹⁴ atoms/cm² to about 5×10¹⁴ atoms/cm².

The ion implantation process used to form the halo regions 45a,b and tip regions 43a,b, and in later steps, optionally to implant ions in the source 56 and drain 60, can be a conventional ion implantation process with angled implants. For example, a non-accelerated plasma can be generated in a torroidal plasma reactor, such as a P3i™ chamber from Applied Materials, Santa Clara, Calif. If this chamber, a spinning torroidal field regenerates the plasma of the dopant-containing gas in the chamber. The dopant ions are typically implanted with an ion implantation energy which is dependent on the species and type of ions, and can be for example, from about 20 eV to about 500 eV. Following the halo and tip implant, the substrate 24 with the partially fabricated FinFET 20 is annealed. For example, a FinFET 20 comprising silicon is annealed at temperatures of at least about 900° C., and a FinFET 20 comprising germanium or other semiconductor compounds are typically annealed at temperatures of from about 500 to about 650° C.

In subsequent processes, one or more of the sacrificial features 37 on the raised fin 32 are removed to eventually form a hollow channel. First, portions of the sacrificial gate dielectric 38 that extend beyond the sidewall spacers 48 are removed by etching (typically during the patterning of the sidewall spacers 48) using conventional RIE processes to form the structure shown in FIG. 2C. A suitable RIE process for etching a sacrificial dielectric 38 comprising silicon dioxide, uses a capacitively coupled plasma of a process gas comprising SF₆ and CH₄, to etch the exposed regions of the sacrificial gate dielectric 38 to form a sacrificial gate dielectric 38 extending under the sidewall spacers 48.

The source 56 and drain 60 are then formed on another portion of the raised fin 32, such as a sidewall portion, by conventional epitaxial growth processes. The source 56 and drain 60 are epitaxially grown lateral extensions which are formed around each raised fin 32, to have the shape shown in FIGS. 2C and 2G1. For example, the source 56 and drain 60 can be formed by epitaxial re-growth of stressed source/drain materials, such as for example, silicon or SiGe after the exposed portions of raised fins are removed by RIE or isotropic etch. A suitable epitaxial growth process comprises a process gas comprising any one or more of SiH₄, Si₂H₆, GeH₄, and HCl. The source 56 and drain 60 can be doped during the epitaxial growth process by introducing dopant gas comprising dopant ion into the epitaxially growing process zone. Alternatively, the source 56 and drain 60 can be implanted with dopant ions after the epitaxial growth process in a separate implantation process to provide the desired semiconducting properties. The ions implanted in the source and drain 56, 60 depend upon the type of semiconductor material. For example, the source and drain 56, 60 of a substrate 24 comprising a silicon wafer can have implanted n-type and/or p-type dopant. The source and drain 56, 60 may be any regions having the opposite conductivity to the subsequently formed channel 72. For example, in one embodiment, when the channel 72 is doped with a n-type dopant, the source 56 and drain 60 are doped with a p-type dopant; and conversely when the channel 72 is doped with a p-type dopant, the source 56 and drain 60 are doped with n-type dopants. In one embodiment, source 56 and drain 60 are implanted with dopant ions comprising either boron or arsenic in an implantation concentration of from about 5×10¹⁹ to about 5×10²° atoms/cm³.

Thereafter, a pre-metal dielectric (PMD) 64 is deposited over the source 56 and drain 60 on the partially fabricated FinFET 20 to form the structure shown in FIG. 2D. The PMD 64 provides electrical insulation between subsequently formed metal interconnect lines that connect the FinFET 20 to other devices formed on the substrate 24. The PMD 64 also serves to gap-fill the spaces between the source 56 and drain 60. The PMD 64 can comprise deposited silicon dioxide, carbon-doped silicon oxide, or even silicate glass (USG). In one version, the PMD 64 is composed of silicon dioxide or carbon-doped silicon oxide. The PMD 64 can be deposited using conventional PE-CVD or high density plasma (HDP-CVD) method to have a thickness of from about 100 to about 200 nm over the top surface of the isolation trenches 36.

After deposition, the PMD 64 is planarized and polished flat using chemical-mechanical polishing to remove a portion of the PMD 64 and expose the top surface of the sacrificial gate electrode 42. When a sacrificial dielectric cap 44 is present, the CMP process can include a first selective polishing step to polish off the PMD 64 to stop on the nitride hardmask, and a second non-selective polishing step to polish off the PMD 64 and nitride hardmask. The sacrificial gate electrode 42 is then etched away and removed by an etching process that is selective to the sidewall spacers 48 and sacrificial gate dielectric 38 to form a hollow trench 66, as shown in FIG. 2D. A suitable etching process comprises an RIE process in which a capacitively coupled plasma of Cl₂/HBr/O₂ is used to etch away the material polysilicon of the sacrificial gate electrode 42 to form the hollow trench 66.

Thereafter, the sacrificial gate dielectric 38 underlying the sacrificial gate electrode 42 is then removed by an isotopic etching process, selective to the PMD 64, sidewall spacers 48, raised fin 32 and source 56 and drain 60, to form and expose a hollow channel 68 over the underlying top surface of the silicon fin 32, as shown in FIG. 2E. A suitable isotropic etching process comprises a wet etching process in which a dilute solution of an acid such as HF is used to etch away the sacrificial gate dielectric 38. Suitable dry etching processes can be conducted in a SICONI type chamber, from Applied Materials, Santa Clara Calif. In the dry etching process, a microwave-activated plasma of NH₃/NF₃ is formed to etch away a sacrificial gate dielectric 38 comprising silicon dioxide. Advantageously, the dry etching process can also serve as a cleaning process for cleaning the underlying surface of the raised fin 32 (which can be composed of silicon) to provide better epitaxial growth of channel material from the cleaned surface in a subsequent selective epitaxial growth process.

In the next step, the hollow channel 68 is filled to form a channel 72 of the FinFET 20 with a selective epitaxial growth (SEG) process, as shown in FIG. 2F. The channel 72 connects the source 56 and drain 60 such that voltage on the gate causes a conductive path to form in the channel 72, allowing current to flow between the source 56 and the drain 60. The channel 72 is formed by SEG to ensure selective growth of the channel material within the hollow channel 68 and not adjoining or surrounding regions or surfaces. Advantageously, formation of the sacrificial features 37 followed by their removal, allows the selective epitaxial growth of many different semiconducting materials to serve as the channel. An SEG process works only because the underlying surface of the hollow channel 68 comprises the top surface of the raised fin 32, which consequently, is made of a semiconducting crystalline material which allows selective nucleation and growth of crystals of the channel material within the hollow channel 68.

Forming a hollow channel 68 and using the SEG process allows formation of different kinds of channel materials by selective growth. Advantageously, insertion of sacrificial features 37 into a partially built FinFET 20 followed by the removal of these features allows the selective epitaxial growth of a channel material which can be any type of semiconductor material. For example, the channel 72 can be composed of silicon, silicon-containing semiconductor compound, germanium-containing semiconductor compound, or even a non-silicon containing semiconductor compound. Suitable compounds that can be formed as the channel include silicon (Si), germanium (Ge), or Group III-V compound semiconductors such as for example silicon germanium (SiGe), gallium arsenide (GaAs), indium phosphate (InP), zinc selenide (ZnSe), indium gallium arsenide (InGaAs) or aluminum gallium arsenide (AlGaAs). In one version, the channel 72 is composed of a semiconductor material which is not pure or doped silicon.

Still further, in conventional processes, it is difficult to form a channel 72 composed of compounds other than pure silicon as such conventional processes required the initial deposition of a thick layer of non-silicon channel material within associated problems of defectivity from lattice mismatch and thermal expansion mismatch stresses, and which often involve non-traditional deposition processes. The present process overcomes these obstacles by forming a thin hollow channel 68, for example having a thickness of from about 1 to about 7 nm, and subsequently filling the hollow channel 68 with a semiconducting material which can be made from alternative materials. For example, wherein the raised fin 32 is composed of a first semiconducting material, the channel 72 can be composed of a second semiconducting material that is a different material than the first semiconducting material. As another example, when the raised fin 72 comprises a material having a first lattice constant, the channel 72 can be made of another material having a second lattice constant that is different lattice constant than the first lattice constant. Thus, when the raised fin 72 comprises pure silicon in the form of a silicon wafer, the channel 72 can be composed of a semiconductor which is not pure silicon or doped silicon, such as germanium, silicon germanium, gallium arsenide, indium phosphate, zinc selenide, indium gallium arsenide, or aluminum gallium arsenide. These materials can have higher electron mobility and thus provide faster conductivity and higher bandwidth than silicon or doped silicon. Advantageously, the present process allows fabrication of a channel 72 composed of these non-silicon materials.

A further advantage is that the present process of forming sacrificial features 37 followed by removal of the sacrificial features 37 allows formation of a thinner channel 72 (with a thickness of from about 2 to 5 nm) than that possible using conventional FinFET fabrication processes in which a thick layer of channel material was deposited to allow subsequent shaping of the channel feature without etching through the entire channel thickness. By pre-forming the hollow channel 68, the dimensions of the channel can be controlled precisely to get the exact shape and thickness of the desired channel 72. Also, conventional processes to deposit a thin second channel layer on top of the raised fins 32 can result in interdiffusion of underlying atoms during any subsequent heating process. The presently described sacrificial or replacement channel process allows the second channel material to be deposited after all the high temperature (or high thermal budget) processes have already been conducted thereby preventing exposure of the channel material to high temperatures. These high temperature processes including, for example, source-drain dopant activation processes. For these reasons, a channel 72 comprising a thin layer can be used in the present FinFET fabrication process without these problems.

Also, selective epitaxial growth (SEG) of a channel material in the empty space of the hollow channel 68 allows precise location of the channel 72 in the optimal place and position for a FinFET 20 without having complex post-deposition processes to etch or otherwise remove extraneous channel material. Conventional channel forming processes require deposition of a thick layer of channel material followed by complex etching processes to remove much of the deposited material to form the desired shape and position of channel. In the present process, the semiconducting channel material is deposited conformal to, namely on and around, the exposed raised fin 32 to form the channel layer in the desired shape and location. A suitable SEG process for depositing silicon in the hollow channel uses a deposition gas comprising SiH₄ or Si₂H₆. A suitable SEG process for depositing a non-silicon material, such as germanium can use a deposition gas such as GeH₄.

Optionally, a capping layer 74 comprising a thin layer of silicon (not shown) can be deposited onto the channel 72 to serve as capping layer for the second channel material. For example, the capping layer 74 can have a thickness of less than about 2 nm, or even about 1 nm. The capping layer 74 of silicon is formed by SEG deposition of silicon.

A gate dielectric layer 78 is then formed over and on the channel 72 as shown in FIG. 2G. The gate dielectric layer 78 can be formed by oxidizing at least a portion of the capping layer 74 in which the capping layer 74 of silicon is heated while being exposed to an oxygen containing environment to form silicon dioxide, followed by deposition of other dielectric material. For example, the capping layer of silicon can be exposed to an oxidizing environment comprising oxygen and hydrogen while it is heated to a temperature of from about 300 to about 500° C. Commercially available gases of H₂ and O₂ can be used. Typically, the gate dielectric layer 78 has a thickness of from about 2 nm to about 4 nm, with the oxidized portion having a thickness of less than about 1 nm.

The gate dielectric layer 78 can also be formed using a conventional CVD process for the deposition of silicon dioxide or other dielectric materials suitable for depositing in a narrow trench and which can electrically isolate the subsequently formed gate electrode 86 from the substrate 24. In one embodiment, gate dielectric layer 78 is formed by atomic layer deposition and is composed of a high-k dielectric material such as, but not limited to, hafnium oxide, zirconium oxide, hafnium silicate, hafnium oxy-nitride or lanthanum oxide and has a thickness in approximately in the range of 1-10 nanometers.

After the channel 72 and gate dielectric layer 78 are fabricated, a gate electrode 86 is formed to complete the FinFET 20 as shown in FIG. 2G. For example, the trench above about the gate dielectric layer 78 and between the sidewall spacers 48 is filled with electrically conducting material to form the gate electrode 86, as shown in FIG. 2G. For example, the gate electrode 86 can be composed of an elemental metal, metal alloy or metal compound such as for example Mo, Ta, Ti, W, TaN, TiN, WN and WSi. The gate electrode 86 can also be a non-metal conductor having an appropriate work function such as, for example, polycrystalline silicon. In one version, the gate electrode comprises titanium or tantalum in a thickness of from about 20 nm to about 100 nm. The gate electrode 86 is formed CVD, or atomic layer deposition (ALD) methods. Suitable CVD methods can be used to deposit metal compounds such as HfN, Mo₂N, TaN, TiN, WN and WSi. In one version, the gate electrode 86 comprises titanium or tantalum, deposited to a thickness of from about 20 nm to about 100 nm. The gate electrode 86 can also be formed of multiple layers of materials, such as work function layers and fill metal layer composed of a metal such as aluminum, copper, titanium, tungsten, titanium nitride, tantalum nitride, and other materials, as for example a transistor fabrication process which uses a sequence of process steps to fabricate a replacement metal gate is disclosed in commonly assigned U.S. Pat. No. 7,892,911 B2, entitled “Metal Gate Electrodes for Replacement Gate Integration Scheme” to Wood et al., which is incorporated by reference herein and in its entirety. The resultant structure as illustrated in FIGS. 2G and 2G1 comprises a completed FinFet 20 having a source 56, drain 60 and channel 72, and isolated by the isolation trenches 36 and the PMD 64, that can function as a good, power effective transistor.

Although exemplary embodiments of the present invention are shown and described, those of ordinary skill in the art may devise other embodiments which incorporate the present invention and which are also within the scope of the present invention. Furthermore, the terms below, above, bottom, top, up, down, first and second and other relative or positional terms are shown with respect to the exemplary embodiments in the figures and are interchangeable. Therefore, the appended claims should not be limited to the descriptions of the preferred versions, materials, or spatial arrangements described herein to illustrate the invention.

1. A method for forming a finFET, the method comprising:
(a) forming a raised fin between isolation trenches on a substrate;
(b) forming a plurality of sacrificial features on at least a portion of the raised fin, the sacrificial features including a sacrificial gate dielectric and a sacrificial gate electrode having sidewalls;
(c) removing one or more of the sacrificial features on the raised fin to form a hollow channel; and
(d) epitaxially growing channel material in the hollow channel to form a channel.

2. A method according to claim 1 comprising at least one of:
(i) the raised fin is composed of silicon; and
(ii) the substrate is a silicon wafer.

3. A method according to claim 1 comprising at least one of:
(i) wherein the raised fin is composed of a first semiconducting material and the channel material is a second semiconducting material that is a different material than the first semiconducting material;
(ii) wherein the raised fin comprises a material having a first lattice constant and the channel material has a second lattice constant that is different lattice constant than the first lattice constant; and
(iii) wherein the channel material is a semiconductor which is not pure silicon or doped silicon.

4. A method according to claim 1 wherein the raised fin comprises silicon and wherein the channel material is composed of germanium, silicon germanium, gallium arsenide, indium phosphate, zinc selenide, indium gallium arsenide or aluminum gallium arsenide.

5. A method according to claim 1 wherein in (b) the sacrificial features comprise a sacrificial dielectric cap formed over the sacrificial gate electrode.

6. A method according to claim 1 wherein after (b) and before (c), sidewall spacers are formed on the sidewalls of the sacrificial gate electrode.

7. A method according to claim 1 comprising at least one of
(i) implanting ions to form tip regions in the raised fin; and
(ii) implanting ions to form halo regions in the substrate.

8. A method according to claim 1 wherein in (b) the sacrificial gate dielectric underlies the sacrificial gate electrode, and wherein (c) comprises selectively etching the sacrificial gate electrode without excessively etching the underlying sacrificial gate dielectric.

9. A method according to claim 1 wherein (c) comprises isotropically etching the sacrificial gate dielectric to form the hollow channel.

10. A method according to claim 1 comprising after (b) forming a source and drain on another portion of the raised fin.

11. A method according to claim 10 comprising depositing pre-metal dielectric over the source and drain.

12. A method according to claim 11 comprising chemical-mechanical polishing the pre-metal dielectric to remove a portion of the pre-metal dielectric.

13. A method according to claim 1 further comprising after (d) forming a gate dielectric layer on the channel, and depositing a gate electrode on the gate dielectric layer.

14. A method for forming a FinFET, the method comprising:
(a) forming a raised fin composed of silicon between shallow isolation trenches on a substrate;
(b) forming a plurality of sacrificial features on at least a portion of the raised fin, the sacrificial features including an underlying sacrificial gate dielectric, an overlying sacrificial gate electrode having sidewalls, and a sacrificial dielectric cap formed over the sacrificial gate electrode;
(c) forming sidewall spacers on the sidewalls of the sacrificial gate electrode;
(d) forming a source and drain on another portion of the silicon raised fin;
(e) removing one or more of the sacrificial features on the raised fin to form a hollow channel; and
(f) epitaxially growing channel material in the hollow channel to form a channel.

15. A method according to claim 14 comprising at least one of:
wherein the raised fin is composed of a first semiconducting material and the channel material is a second semiconducting material that is a different material than the first semiconducting material;
(ii) wherein the raised fin comprises a material having a first lattice constant and the channel material has a second lattice constant that is different lattice constant than the first lattice constant; and
(iii) wherein the channel material is a semiconductor which is not pure silicon or doped silicon.

16. A method according to claim 14 comprising after (c) at least one of
(i) implanting ions to form tip regions in the raised fin; and
(ii) implanting ions to form halo regions in the substrate.

17. A method according to claim 14 wherein (e) comprises at least one of
(i) selectively etching the sacrificial gate electrode without excessively etching the sacrificial gate dielectric; and
(ii) isotropically etching the sacrificial gate dielectric to form the hollow channel.

18-20. (canceled)

21. A method for forming a FinFET, the method comprising:
(a) forming a raised fin composed of silicon semiconducting material between shallow isolation trenches on a substrate;
(b) forming a plurality of sacrificial features on at least a portion of the raised fin, the sacrificial features including an underlying sacrificial gate dielectric, an overlying sacrificial gate electrode having sidewalls, and a sacrificial dielectric cap formed over the sacrificial gate electrode;
(c) forming sidewall spacers on the sidewalls of the sacrificial gate electrode;
(d) forming a source and drain on another portion of the raised fin;
(e) removing one or more of the sacrificial features on the raised fin to form a hollow channel; and
(f) epitaxially growing channel material in the hollow channel to form a channel, the channel material being a semiconducting material that is a different material than the silicon semiconducting material.

22. A method according to claim 21 wherein (e) comprises at least one of
(i) selectively etching the sacrificial gate electrode without excessively etching the sacrificial gate dielectric; and
(ii) isotropically etching the sacrificial gate dielectric to form the hollow channel.

23. A method according to claim 21 comprising after (b) forming a source and drain on another portion of the raised fin.
